(19) United States
(12) Patent Application Publication
(10) Pub. No.: US 2025/0336351 A1
(43) Pub. Date: Oct. 30, 2025

(54) DISPLAY DEVICE COMPRISING LIGHT-EMITTING DIODE (LED) PIXEL CIRCUIT ENHANCING LUMINANCE UNIFORMITY

(71) Applicant: NOVATEK Microelectronics Corp., Hsin-Chu (TW)

(72) Inventor: Min Huang, Taoyuan City (TW)

(73) Assignee: NOVATEK Microelectronics Corp., Hsin-Chu (TW)

(21) Appl. No.: 18/646,777

(22) Filed: Apr. 26, 2024

(51) Int. Cl. G09G 3/3233; H01L 25/16

(52) U.S. Cl. CPC G09G 3/3233; H01L 25/167; G09G 2300/0852; G09G 2300/0861; G09G 2320/0233

(57) ABSTRACT

A pixel circuit includes a sample circuit, a first transistor, a second transistor, a third transistor, a light-emitting diode, and a fourth transistor. The first transistor includes a control terminal coupled to the sample circuit, a first terminal coupled to a supply terminal, and a second terminal. The second transistor coupled to the control terminal and the second terminal of the first transistor. The third transistor includes a first terminal coupled to the second terminal of the first transistor, and a second terminal. The light-emitting diode includes a first terminal coupled to the second terminal of the third transistor, and a second terminal coupled to a ground terminal. The fourth transistor includes a first terminal coupled to the first terminal of the light-emitting diode and a second terminal, and a second terminal coupled to a reset terminal.

### BACKGROUND OF THE INVENTION

### 1. Field of the Invention

The invention relates to display technology, and in particular, to a pixel circuit for enhancing luminance uniformity and display device thereof.

### 2. Description of the Prior Art

Light-emitting diodes (LEDs) such as micro-LEDs are microscopic light-emitting elements known for the longevity owing to low power usage. The LEDs are small in size, e.g., the size of micro-LEDs may be 100 μm. The LEDs are light in weight, and can be arranged in pixel arrays of display panels to offer a fast response speed, high resolution, and a wide viewing angle.

Each pixel element in the pixel arrays employs silicon-based metal-oxide-semiconductor field-effect transistors (MOSFETs) to control the LEDs. However, the process variation would affect the threshold voltages of the driving MOSFETs, resulting in uneven luminance across the pixel array as the same gate voltage applied to the driving MOSFETs would generate different driving currents.

Moreover, given that the mobility of the silicon-based MOSFET is significantly higher than that of the alternative substrate-based MOSFET (e.g., glass-based MOSFET), and the luminance of the LED is adjusted by the driving current at the picoampere (pA) to nanoampere (nA) level, the operation range of the gate voltage of the driving MOSFET is very limited for delivering the required driving current, requiring a precise gate voltage control and complicating the data generation process.

Further, the micro-OLED-based pixel array is high in pixel density (high dots per inch (dpi)), and thus, no DC current is allowed in the pixel element except in the emission stage. Furthermore, the pixel element employs a small hold capacitor to store the gate voltage without occupy too much circuit area. However, the hold capacitor forms a leakage path between the supply terminal and the ground terminal, affecting the gate voltage of the driving MOSFET.

### SUMMARY OF THE INVENTION

According to an embodiment of the invention, a pixel circuit includes a sample circuit, a first transistor, a second transistor, a third transistor, a light-emitting diode, and a fourth transistor. The first transistor includes a control terminal coupled to the sample circuit, a first terminal coupled to a supply terminal, and a second terminal. The second transistor includes a first terminal coupled to the control terminal of the first transistor, and a second terminal coupled to the second terminal of the first transistor. The third transistor includes a first terminal coupled to the second terminal of the first transistor, and a second terminal. The light-emitting diode includes a first terminal coupled to the second terminal of the third transistor, and a second terminal coupled to a ground terminal. The fourth transistor includes a first terminal coupled to the first terminal of the light-emitting diode and a second terminal, and a second terminal coupled to a reset terminal.

According to another embodiment of the invention, a display device includes a plurality of scan lines, a plurality of data lines and a pixel array. The sample circuit is coupled to one of the plurality of scan lines and one of the plurality of data lines. The pixel array includes a row of pixel circuits, each pixel circuit including a sample circuit, a first transistor, a second transistor, a third transistor, a light-emitting diode, and a fourth transistor. The first transistor includes a control terminal coupled to the sample circuit, a first terminal coupled to a supply terminal, and a second terminal. The second transistor includes a first terminal coupled to the control terminal of the first transistor, and a second terminal coupled to the second terminal of the first transistor. The third transistor includes a first terminal coupled to the second terminal of the first transistor, and a second terminal. The light-emitting diode includes a first terminal coupled to the second terminal of the third transistor, and a second terminal coupled to a ground terminal. The fourth transistor includes a first terminal coupled to the first terminal of the light-emitting diode and a second terminal, and a second terminal coupled to a reset terminal.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic diagram of a pixel circuit according to an embodiment of the invention.

FIG. 2 is a block diagram of a display device utilizing the pixel circuit in FIG. 1.

FIGS. 3A to 3D are schematic diagrams of the pixel circuit in FIG. 1 in 4 operation modes, respectively.

FIG. 4 shows waveforms of the pixel circuit in FIG. 1.

FIG. 5 is a schematic diagram of a pixel circuit according to another embodiment of the invention.

FIGS. 6A to 6D are schematic diagrams of the pixel circuit in FIG. 5 in 4 operation modes, respectively.

FIG. 7 is a schematic diagram of a pixel circuit according to another embodiment of the invention.

FIG. 8 is a schematic diagram of a pixel circuit according to another embodiment of the invention.

### DETAILED DESCRIPTION

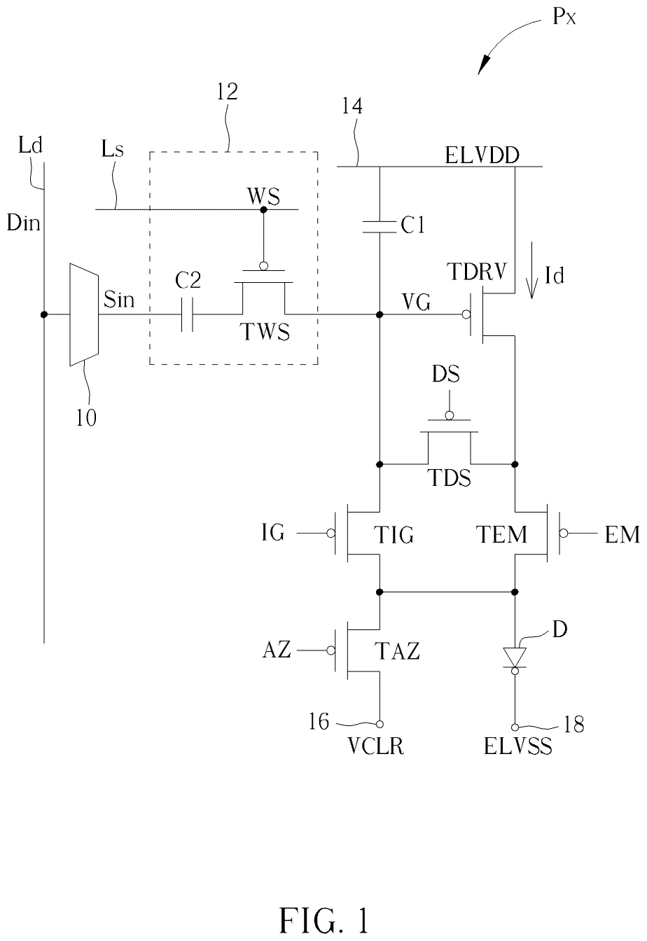

FIG. 1 is a schematic diagram of a pixel circuit Px according to an embodiment of the invention. The pixel circuit Px may include a demultiplexer 10, a sample circuit 12, a driving transistor TDRV (first transistor), a compensation transistor TDS (second transistor), an emission control transistor TEM (third transistor), a reset transistor TAZ (fourth transistor), and a light-emitting diode D to display a pixel of an image, and may be fabricated on a silicon substrate. The pixel circuit Px may be initiated and compensated for the threshold voltage of the driving transistor TDRV in a precise manner, enhancing luminance uniformity of a display panel.

The demultiplexer 10 may be coupled to a data line Ld to receive a data signal Din and output an input signal Sin. The data signal Din conveys pixel data for a column of pixel circuits Px coupled to the data line Ld, and the input signal Sin conveys pixel data for a given pixel circuits Px. Each piece of pixel data may be represented by a gray level. The sample circuit 12 may sample a voltage in the input signal Sin according to a scan signal WS to acquire a piece of pixel data. The sample circuit 12 may include a sense capacitor C2 and a sample transistor TWS (fifth transistor). The sense capacitor C2 includes a first terminal coupled to a data line Ld via the demultiplexer 10 to receive the input signal Sin, and a second terminal. The sample transistor TWS includes a control terminal coupled to a scan line Ls to receive the scan signal WS, a first terminal coupled to the second terminal of the sense capacitor C2, and a second terminal. The pixel circuit Px may be operated in an initial mode, a compensation mode, a program mode or an emission mode. The sample transistor TWS may be turned on to enable the sense capacitor C2 to sense an offset voltage in the initial mode and the compensation mode, and sense a data voltage in the program mode, and turned off after the data voltage is stabilized in the emission mode, for the pixel circuit Px in the next row to gain access to the data line.

The driving transistor TDRV includes a control terminal coupled to the second terminal of the sample transistor TWS to receive a gate voltage VG, a first terminal coupled to a supply terminal 14, and a second terminal. The supply terminal 14 may provide a supply voltage ELVDD, e.g., 5V. The compensation transistor TDS includes a control terminal configured to receive a compensation signal DS, a first terminal coupled to the control terminal of the driving transistor TDRV, and a second terminal coupled to the second terminal of the driving transistor TDRV. The emission control transistor TEM includes a control terminal configured to receive an emission control signal EM, a first terminal coupled to the second terminal of the driving transistor TDRV, and a second terminal. The light-emitting diode (LED) D includes a first terminal (e.g., anode) coupled to the second terminal of the emission control transistor TEM, and a second terminal (e.g., cathode) coupled to a ground terminal 18. The supply terminal 14 may provide a ground voltage ELVSS less than the supply voltage ELVDD, e.g., 0V. The reset transistor TAZ includes a control terminal configured to receive a reset signal AZ, a first terminal coupled to the first terminal of the light-emitting diode D and a second terminal, and a second terminal coupled to a reset terminal 16. The reset terminal 16 may provide a reset voltage VCLR less than the threshold voltage of the light-emitting diode D to turn off the light-emitting diode D, e.g., −0.8V.

The pixel circuit Px may further include an isolation transistor TIG (sixth transistor) including a control terminal configured to receive an isolation signal IG, a first terminal coupled to the first terminal of the compensation transistor TDS, and a second terminal coupled to the first terminal of the reset transistor TAZ. The isolation transistor TIG may be turned off to disconnect a current path between the supply terminal 14 and the reset terminal 16, thereby reducing the static power loss. In some embodiments, the isolation transistor TIG may be omitted from the pixel circuit Px and the control terminal of the driving transistor TDRV may be coupled to the first terminal of the reset transistor TAZ

The pixel circuit Px may further include a hold capacitor C1 including a first terminal coupled to the supply terminal 14, and a second terminal coupled to the control terminal of the driving transistor TDRV. The hold capacitor C1 and the parasitic capacitor at the control terminal the driving transistor TDRV may reduce the bulk leakage current of the sample transistor TWS, and may store the threshold voltage of the driving transistor TDRV. In some examples, the hold capacitor C1 may reduce the bulk leakage current of the sample transistor TWS by 37% during the emission mode, enhancing the image stability of the pixel array 24. In some embodiments, the hold capacitor C1 may be omitted from the pixel circuit Px, and the threshold voltage of the driving transistor TDRV may be stored by the parasitic capacitor at the control terminal of the driving transistor TDRV. The hold capacitor C1 and the sense capacitor C2 may serve as a voltage divider to reduce the input signal Sin, thereby enhancing the step size of the gray level and increasing the operation range of the input signal Sin while delivering the required driving current Id. For example, the voltage divider may increase each gray level of the input signal Sin to more than 10 mV from the original level of less than 1 mV, while delivering the driving current Id at the picoampere (pA) to nanoampere (nA) level.

The light-emitting diode D may be an organic LED, a micro-LED, a mini-LED, a quantum dot LED, or other types of LEDs. The sample transistor TWS, the driving transistor TDRV, the compensation transistor TDS, the emission control transistor TEM, the isolation transistor TIG, and the reset transistor TAZ may be P-type metal-oxide-semiconductor field-effect transistors (MOSFETs). It would be apparent to those skilled in the art to replace one or more of the P-type MOSFETs in the pixel circuit Px with one or more N-type MOSFETs without deviating from the principle of the invention.

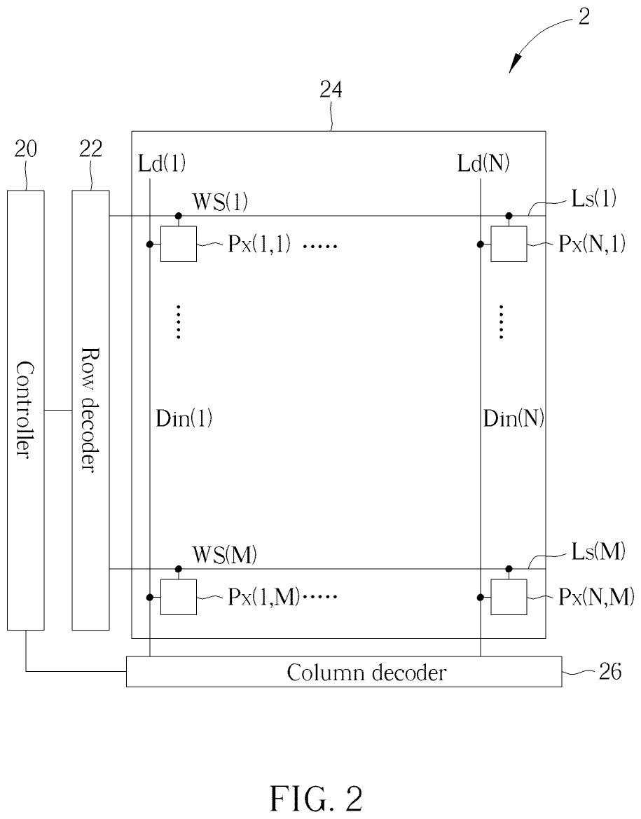

FIG. 2 is a block diagram of a display device 2 utilizing the pixel circuit Px in FIG. 1. The display device 2 may include data lines Ld(1) to Ld(N), scan lines Ls(1) to Ls(M), a controller 20, a row decoder 22, a pixel array 24, and a column decoder 26, n, m being positive integers, e.g., n=1920, m=1080. The controller 20 may be coupled to the row decoder 22 and the column decoder 26, the row decoder 22 may be coupled to the pixel array 24 via the scan lines Ls(1) to Ls(M), the column decoder 26 may be coupled to the pixel array 24 via the data lines Ld(1) to Ld(N).

The pixel array 24 includes pixel circuits Px(1, 1) to Px(N,M) arranged in M rows and N columns of pixel circuits, each pixel circuit having a circuit configuration similar to the pixel circuit Px in FIG. 1. The pixel circuits coupled to the same scan line are referred to as a row of pixel circuits, e.g., the pixel circuits Px(1,1) to Px(N,1) is the first row of pixel circuits. The pixel circuits coupled to the same data line are referred to as a column of pixel circuits, e.g., the pixel circuits Px(1,1) to Px(1,M) is the first column of pixel circuits.

The controller 20 may control the row decoder 22 to generate and transmit scan signals WS(1) to WS(M) to the first to the Mth rows of the pixel circuits via the scan lines Ls(1) to Ls(M), respectively. Further, the controller 20 may control the column decoder 26 to generate and transmit data signals Din(1) to Din(N) to the first to the Nth columns of the pixel circuits via the data lines Ld(1) to Ld(N), respectively. In some embodiments, the column decoder 26 may include a data source circuit to generate the data signals Din(1) to Din(N). The data source circuit may be a source operational amplifier. Furthermore, the controller 20 may control the row decoder 22 to generate and transmit other control signals (including reset signals AZ, isolation signals IG, compensation signals DS, and emission control signals EM) to the first to the Mth rows of the pixel circuits, respectively. For a given row of pixel circuits, the row of pixel circuits may receive the same scan signal WS, reset signal AZ, compensation signal DS, and emission control signal EM, and each pixel circuit in the row of pixel circuits may receive a corresponding data signal Din in the data signals Din(1) to Din(N).

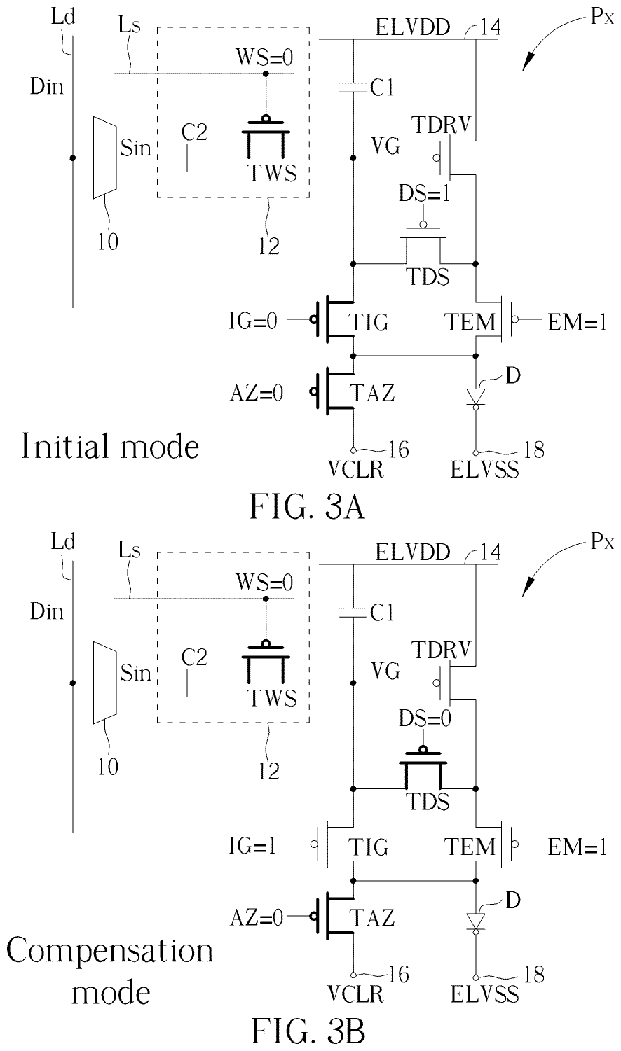

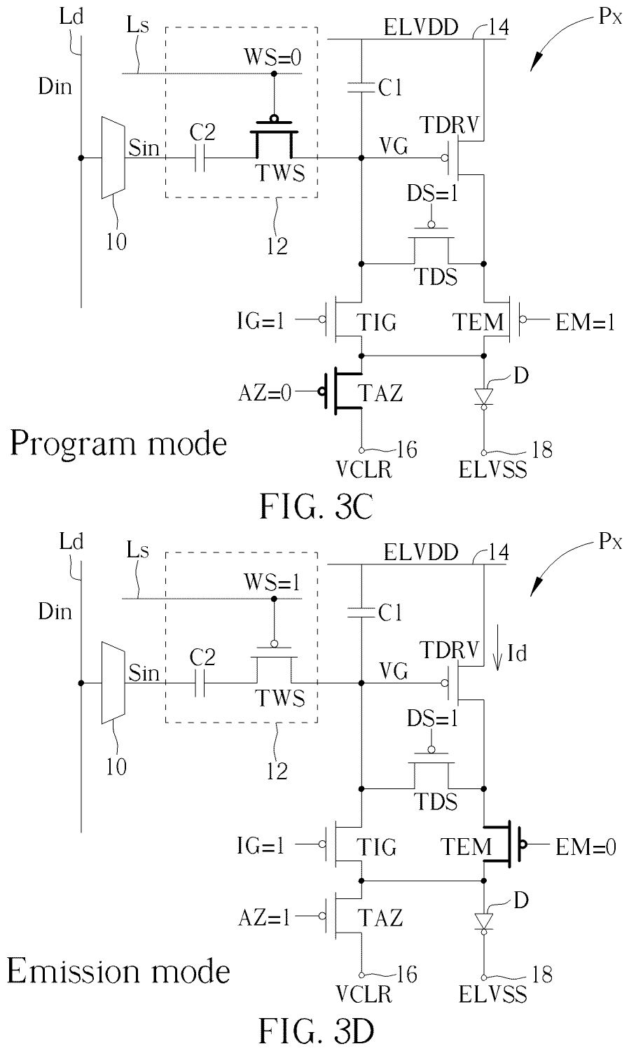

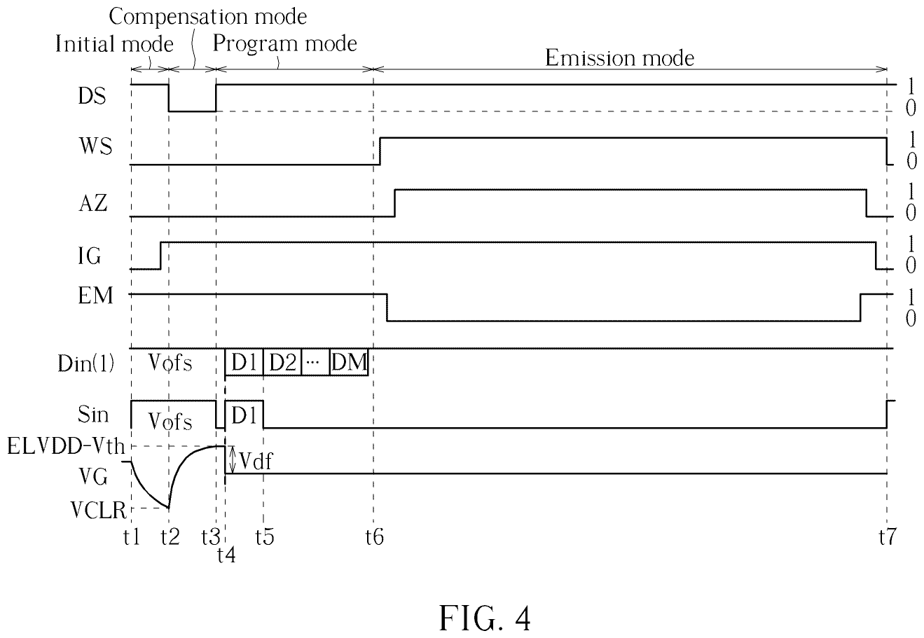

The pixel circuit Px may receive the scan signal WS, the input signal Sin, the reset signal AZ, the isolation signal IG, the compensation signal DS, and the emission control signal EM to be operated in the initial mode, the compensation mode, the program mode or the emission mode, as shown in FIGS. 3A to 3D and 4. Details of the 4 operation modes will be provided in the subsequent paragraphs.

FIGS. 3A to 3D are schematic diagrams of the pixel circuit Px in FIG. 1 in the initial mode, the compensation mode, the program mode and the emission mode, respectively. FIG. 4 shows waveforms of the pixel circuit Px in the 4 operation modes. The operation modes of the pixel circuit Px(1, 1) may be explained with reference to FIGS. 3A to 3D and 4.

In FIG. 4, between Time t1 and Time t2, the pixel circuit Px(1,1) is configured in the initial mode. In the initial mode, the compensation signal DS is set to a logical “1” (e.g., 5V), the scan signal WS is set to a logical “0” (e.g., 0V), the reset signal AZ is set to the logical “0”, the isolation signal IG is set to the logical “0”, and the emission control signal EM is set to the logical “1”. The data signal Din(1) is set to an offset voltage Vofs, and the input signal Sin of the pixel circuit Px(1,1) is set to the offset voltage Vofs according to the data signal Din(1). The offset voltage Vofs is a fixed voltage level, and may the maximum value (e.g., 5V) or the minimum value (e.g., 0V) of the data signal Din(1). In the embodiment, the offset voltage Vofs may be the maximum value of the data signal Din(1). The gate voltage VG decreases from a previous voltage level to the reset voltage VCLR, ensuring accurate extraction of the threshold voltage Vth of the driving transistor TDRV in the subsequent operation.

Referring to FIG. 3A, in the initial mode, the reset transistor TAZ is turned on to reset the voltage at the first terminal of the light-emitting diode D to the reset voltage VCLR (e.g., −0.8V), deactivating the light-emitting diode D. The isolation transistor TIG is turned on to set the gate voltage VG to the reset voltage VCLR. While the gate voltage VG is less than a voltage (ELVDD−Vth), since the drain of the driving transistor TDRV may be regarded as having high impedance, there is no current flowing through the driving transistor TDRV, reducing or eliminating the DC power losses. Vth is the absolute value of the threshold voltage of the driving transistor TDRV. The sample circuit 12 is enabled by turning on the sample transistor TWS to receive the offset voltage Vofs from the data source circuit, so as to establish a voltage (Vofs-VCLR) across the sample capacitor C2 and establish a voltage (ELVDD-VCLR) across the hold capacitor C1. Further, the compensation transistor TDS and the emission control transistor TEM are turned off to cut off the DC (direct current) current path between the supply terminal 14 and the ground terminal 18 and the DC current path between the supply terminal 14 and reset terminal 16, further reducing or eliminating the DC power losses.

Returning to FIG. 4, between Time t2 and Time t3, the pixel circuit Px(1,1) is configured in the compensation mode. In the compensation mode, the compensation signal DS is set to the logical “0”, the scan signal WS remains at the logical “0”, the reset signal AZ remains at the logical “0”, the isolation signal IG is set to the logical “1”, and the emission control signal EM remains at the logical “1”. The data signal Din(1) remains at the offset voltage Vofs, and the input signal Sin of the pixel circuit Px(1,1) remains at the offset voltage Vofs accordingly. The gate voltage VG increases from the reset voltage VCLR to the voltage (ELVDD−Vth).

Referring to FIG. 3B, in the compensation mode, the compensation transistor TDS is turned on to couple the source of the driving transistor TDRV to the control terminal of the driving transistor TDRV via the compensation transistor TDS, connecting the driving transistor TDRV in a diode configuration and setting the gate voltage VG to the voltage (ELVDD−Vth). The sample circuit 12 remains enabled by continuing to turn on the sample transistor TWS, so as to establish a voltage (Vofs−(ELVDD−Vth)) across the sample capacitor C2 and establish a voltage (ELVDD−(ELVDD−Vth)) across the hold capacitor C1. Thus, the hold capacitor C1 holds the threshold voltage Vth of the driving transistor TDRV for subsequent uses. The reset transistor TAZ remains on to deactivate the light-emitting diode D. Further, the isolation transistor TIG is turned off and the emission control transistor TEM is turned off to disconnect the DC current path between the supply terminal 14 and the ground terminal 18 and the DC current path between the supply terminal 14 and reset terminal 16, reducing or eliminating the DC power losses.

Referring to FIG. 4, between Time t3 and Time t6, the pixel circuit Px(1,1) is configured in the program mode. In the program mode, the compensation signal DS is set to the logical “1”, the scan signal WS remains at the logical “0”, the reset signal AZ remains at the logical “0”, the isolation signal IG remains at the logical “1”, and the emission control signal EM remains at the logical “1”. The data signal Din(1) is sequentially set to data voltages D1, D2, . . . , DM to feed into the pixel circuits Px(1,1), Px(1,2), . . . , Px(1,M) in the first column of pixel circuits Px via the data line Ld(1). Each of the data voltages D1, D2, . . . , DM ranges between the maximum value and the minimum value. For example, the data voltage D1 may be 3V. In some embodiments, the data signal Din(1) is set to the data voltage D1 and the input signal Sin of the pixel circuit Px(1,1) is set to the corresponding data voltage D1 between Time t4 and Time t5. The gate voltage VG decreases from the voltage (ELVDD−Vth) by a voltage difference Vdf, the voltage difference Vdf being expressed by Equation Eq(1):

$$Vdf = ( Vofs - Vdat ) * C 2 / ( C 1 + C 2 ) \qquad Eq ( 1 )$$

where Vofs is the offset voltage;
Vdat is the data voltage;
C1 is the capacitance of the hold capacitor C1; and
C2 is the capacitance of the sense capacitor C2.

In the example, the data voltage Vdat of the pixel circuit Px(1,1) is the data voltage D1. The sense capacitor C2 may sense the input signal Sin of the pixel circuit Px(1,1) dropping from the offset voltage Vofs to the data voltage D1, and the voltage divider formed by the hold capacitor C1 and the sense capacitor C2 may convert the voltage drop (Vofs−D1) into the voltage difference Vdf in the gate voltage VG by a scaling down factor of C2/(C1+C2). That is, the step size of the gray level conveyed by the data signal Din(1) may be enhanced by a factor of (C1+C2)/C2. Since the data voltage D1 may be attenuated by the scaling down factor of C2/(C1+C2), the data source circuit may use the enhanced step size of the gray level to generate the data voltage D1, simplifying the data generation process. For example, if C1=9*C2, the step size of the gray level may increase to 10 mV from the original 1 mV, being beneficial for the data source circuit to generate the data voltage D1. The pixel circuit Px may update the gate voltage VG according to Equation Eq(2):

$$\begin{matrix}VG = ( ELVDD - Vth ) - Vdf \\ = ( ELVDD - Vth ) - ( Vofs - Vdat ) * C 2 / ( C 1 + C 2 )\end{matrix} \qquad Eq ( 2 )$$

where (ELVDD−Vth) is the gate voltage VG upon the start of the program mode; and
Vdf is the voltage difference accounting for the voltage drop of the gate voltage VG from the offset voltage Vofs to the data voltage Vdat in the program mode.

According to Equation Eq(2), the gate voltage VG is negatively correlated to the voltage difference Vdf. The larger the voltage difference Vdf is, the smaller the gate voltage VG is, and the larger the driving current Id is generated by the driving transistor TDRV. The voltage stored the hold capacitor C1 is Vth+(Vofs−Vdat)*C2/(C1+C2). In the example, the hold capacitor C1 of the pixel circuit Px(1,1) stores Vth+(Vofs−D1)*C2/(C1+C2). In a similar manner, the pixel circuits Px(1,2) to Px(1,M) may sequentially retrieve the data voltages D2 to DM to update respective gate voltages VG according to Equation Eq(2) between Time t5 and Time t6. For example, the pixel circuit Px(1,2) may update the gate voltage VG to (ELVDD−Vth)−(Vofs−D2)*C2/(C1+C2) and the hold capacitor C1 of the pixel circuit Px(1,2) may store Vth+(Vofs−D2)*C2/(C1+C2), and the pixel circuit Px(1,M) may update the gate voltage VG to (ELVDD−Vth)−(Vofs−DM)*C2/(C1+C2) and the hold capacitor C1 of the pixel circuit Px(1,M) may store Vth+(Vofs−DM)*C2/(C1+C2). In the program mode, the data source circuit transmits the offset voltage Vofs and the data voltage D1 via the data line Ld(1), rather than transmitting via two separate lines and selected by a switch, thus saving one line and one switch.

Referring to FIG. 3C, in the program mode, the sample circuit 12 remains enabled by continuing to turn on the sample transistor TWS, and the compensation transistor TDS is turned off to update the gate voltage VG according to Equation Eq(2). The reset transistor TAZ remains on to deactivate the light-emitting diode D. Further, the isolation transistor TIG is turned off and the emission control transistor TEM is turned off to disconnect the DC current path between the supply terminal 14 and the ground terminal 18 and the DC current path between the supply terminal 14 and reset terminal 16, reducing or eliminating the DC power losses.

Referring to FIG. 4, between Time t6 and Time t7, the pixel circuit Px(1,1) is configured in the emission mode. In the emission mode, the compensation signal DS remains at the logical “1”, the scan signal WS is switched to the logical “1”, the reset signal AZ is switched to the logical “1”, the isolation signal IG remains at the logical “1”, and the emission control signal EM is switched to the logical “0”. The data signal Din(1) may be floating or carry any voltage, and the input signal Sin of the pixel circuits Px(1,1) may be set to the ground voltage. The gate voltage VG is maintained at (ELVDD−Vth)−Vdf.

Referring to FIG. 3D, in the emission mode, the sample circuit 12 is disabled by turning off the sample transistor TWS, so as to disable the first row of pixel circuits Px. In turn, the second row of pixel circuits Px is enabled to operate. As a result, the sense capacitor C2 is disconnected from the control terminal of the driving transistor TDRV, and the driving transistor TDRV is driven by the voltage (Vth+(Vofs−Vdat)*C2/(C1+C2)) in the hold voltage C1 to generate the driving current Id, as expressed by Equation Eq(3):

$$\begin{matrix}Id = 0.5 * K * ( VSG - Vth ) \hat{} 2 \\ = 0.5 * K * [ ( Vofs - Vdat ) * C 2 / ( C 1 + C 2 ) ] \hat{} 2\end{matrix} \qquad Eq ( 3 )$$

where K=μ*Cox*(W/L);
   μ is the mobility of the driving transistor TDRV;
Cox is the gate oxide capacitance of the driving transistor TDRV;
W and L are the width and length of the driving transistor TDRV, respectively;
VSG=VS−VG=ELVDD−(ELVDD−Vth)−Vdf=Vth−Vdf; and
Vdf is the voltage difference accounting for the voltage drop of the gate voltage VG from the offset voltage Vofs to the data voltage Vdat.

The emission control transistor TEM is turned on to drive the light-emitting diode D using the driving current Id. According to Equation Eq(3), the driving current Id is independent of the threshold voltage Vth of the driving transistor TDRV and dependent on (Vofs−Vdat) in each pixel circuit Px, thus the luminance of the light-emitting diode D is controlled by the operation range of the data source circuit without being affected by the threshold voltage Vth of the driving transistor TDRV in each pixel circuit Px, achieving luminance uniformity of the pixel array 24. The isolation transistor TIG, the reset transistor TAZ, and the compensation transistor TDS are turned off to disconnect the DC current path between the supply terminal 14 and reset terminal 16, reducing or eliminating the DC power losses.

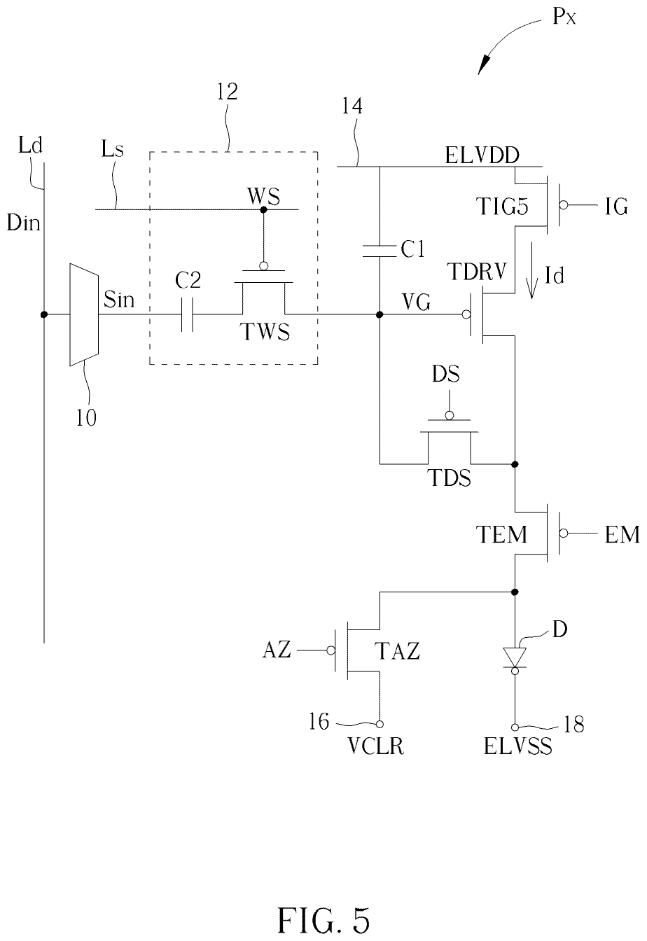

FIG. 5 is a schematic diagram of a pixel circuit Px according to another embodiment of the invention. The pixel circuit Px in FIG. 5 is different from the pixel circuit Px in FIG. 1 in the configuration of an isolation transistor TIG5 (sixth transistor), and will be discussed in more detail in the following paragraphs. The other components in FIG. 5 are configured and operated in a manner similar to those in FIG. 1, and the explanation therefor will be omitted here for brevity.

The isolation transistor TIG5 includes a control terminal configured to receive the isolation signal IG, a first terminal coupled to the supply terminal 14; and a second terminal coupled to the first terminal of the driving transistor TDRV. The first terminal of the reset transistor TAZ is not directly connected to the control terminal of the driving transistor TDRV. The isolation transistor TIG5 may be turned off to disconnect a current path between the supply terminal 14 and the reset terminal 16, thereby reducing static power consumption.

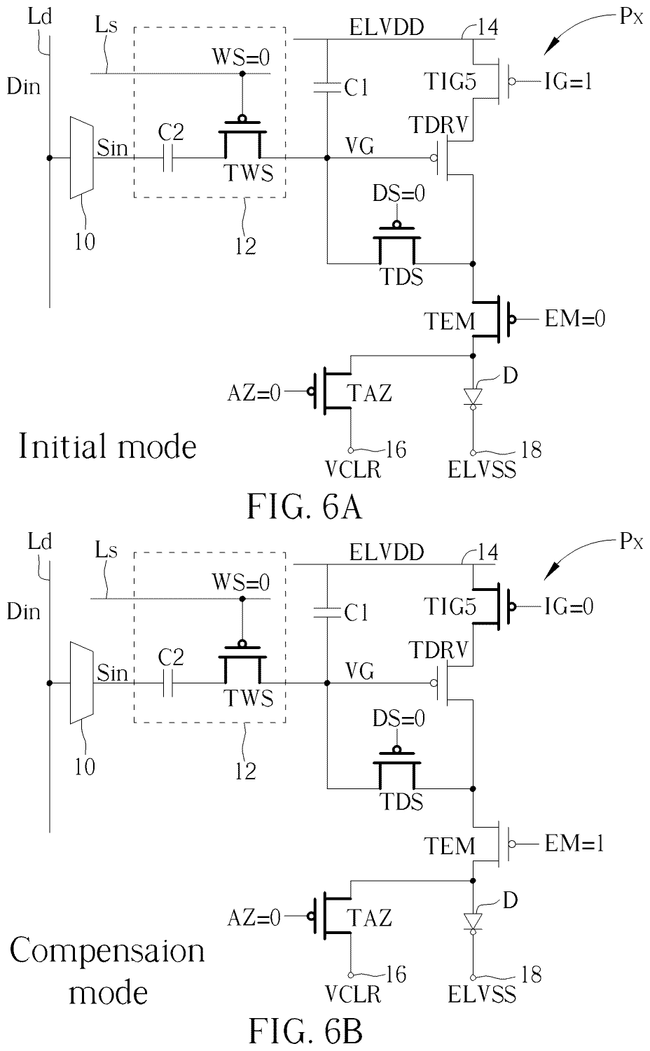

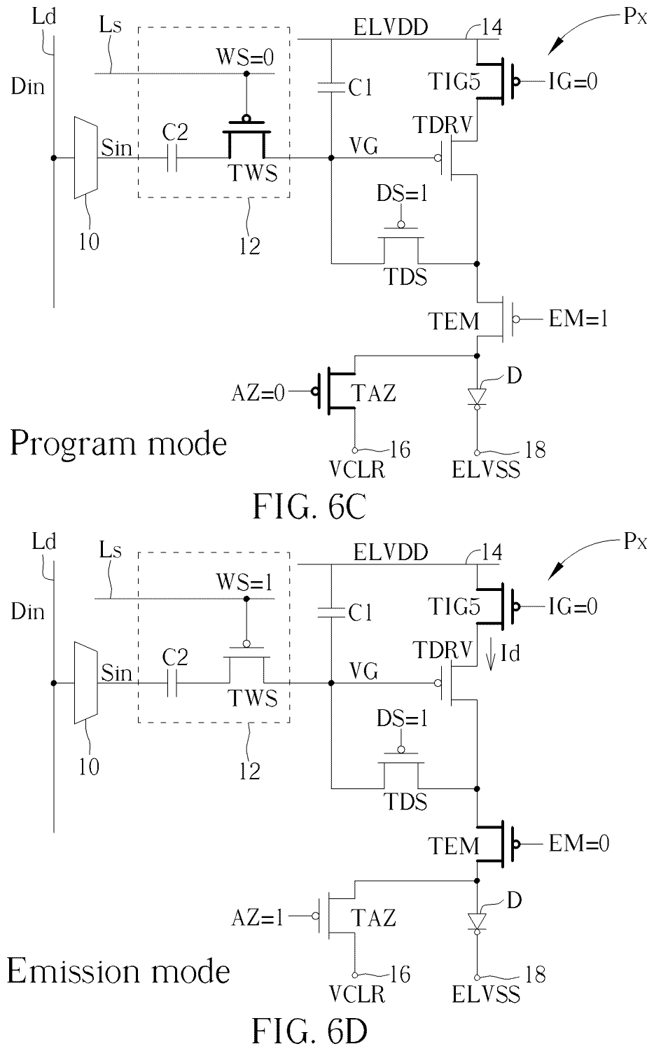

FIGS. 6A to 6D are schematic diagrams of the pixel circuit Px in FIG. 5 in in the initial mode, the compensation mode, the program mode and the emission mode, respectively. The operation modes of the pixel circuit Px(1,1) may be explained with reference to FIGS. 6A to 6D.

Referring to FIG. 6A, in the initial mode, the reset transistor TAZ is turned on to reset the voltage at the first terminal of the light-emitting diode D to the reset voltage VCLR (e.g., −0.8V), deactivating the light-emitting diode D. The compensation transistor TDS and the emission control transistor TEM are turned on to set the gate voltage VG to the reset voltage VCLR. While the gate voltage VG is less than a voltage (ELVDD−Vth), since the drain of the driving transistor TDRV may be regarded as having high impedance, there is no current flowing through the driving transistor TDRV, reducing or eliminating the DC power losses. The sample circuit 12 is enabled by turning on the sample transistor TWS to receive the offset voltage Vofs from the data source circuit, so as to establish a voltage (Vofs−VCLR) across the sample capacitor C2 and establish a voltage (ELVDD−VCLR) across the hold capacitor C1. Further, the isolation transistor TIG5 is turned off to cut off the DC current path between the supply terminal 14 and the ground terminal 18 and the DC current path between the supply terminal 14 and reset terminal 16, further reducing or eliminating the DC power losses.

Referring to FIG. 6B, in the compensation mode, the compensation transistor TDS remains on to couple the source of the driving transistor TDRV to the control terminal of the driving transistor TDRV via the compensation transistor TDS, connecting the driving transistor TDRV in a diode configuration and setting the gate voltage VG to the voltage (ELVDD−Vth). The sample circuit 12 remains enabled by continuing to turn on the sample transistor TWS, and the isolation transistor TIG5 is turned on to establish a voltage (Vofs−(ELVDD−Vth)) across the sample capacitor C2 and establish a voltage (ELVDD−(ELVDD−Vth)) across the hold capacitor C1. Thus, the hold capacitor C1 holds the threshold voltage Vth of the driving transistor TDRV for subsequent uses. The reset transistor TAZ remains on to deactivate the light-emitting diode D. Further, the emission control transistor TEM is turned off to disconnect the DC current path between the supply terminal 14 and the ground terminal 18 and the DC current path between the supply terminal 14 and reset terminal 16, reducing or eliminating the DC power losses.

Referring to FIG. 6C, in the program mode, the sample circuit 12 remains enabled by continuing to turn on the sample transistor TWS, and the compensation transistor TDS is turned off to update the gate voltage VG according to Equation Eq(2). The voltage across the hold capacitor C1 is Vth+(Vofs−Vdat)*C2/(C1+C2). The reset transistor TAZ remains on to deactivate the light-emitting diode D. The isolation transistor TIG5 is turned on. The emission control transistor TEM is turned off to disconnect the DC current path between the supply terminal 14 and the ground terminal 18 and the DC current path between the supply terminal 14 and reset terminal 16, reducing or eliminating the DC power losses.

Referring to FIG. 6D, in the emission mode, the sample circuit 12 is disabled by turning off the sample transistor TWS, so as to disable the first row of pixel circuits Px. In turn, the second row of pixel circuits Px is enabled to operate. As a result, the sense capacitor C2 is disconnected from the control terminal of the driving transistor TDRV, and the driving transistor TDRV is driven by the voltage (Vth+(Vofs−Vdat)*C2/(C1+C2)) in the hold voltage C1 to generate the driving current Id, as expressed by Equation Eq(3). The isolation transistor TIG5 and the emission control transistor TEM are turned on to drive the light-emitting diode D using the driving current Id. According to Equation Eq(3), the driving current Id is independent of the threshold voltage Vth of the driving transistor TDRV and dependent on (Vofs−Vdat) in each pixel circuit Px, thus the luminance of the light-emitting diode D is controlled by the operation range of the data source circuit without being affected by the threshold voltage Vth of the driving transistor TDRV in each pixel circuit Px, achieving luminance uniformity of the pixel array 24. The reset transistor TAZ, and the compensation transistor TDS are turned off to disconnect the DC current path between the supply terminal 14 and reset terminal 16, reducing or eliminating the DC power losses.

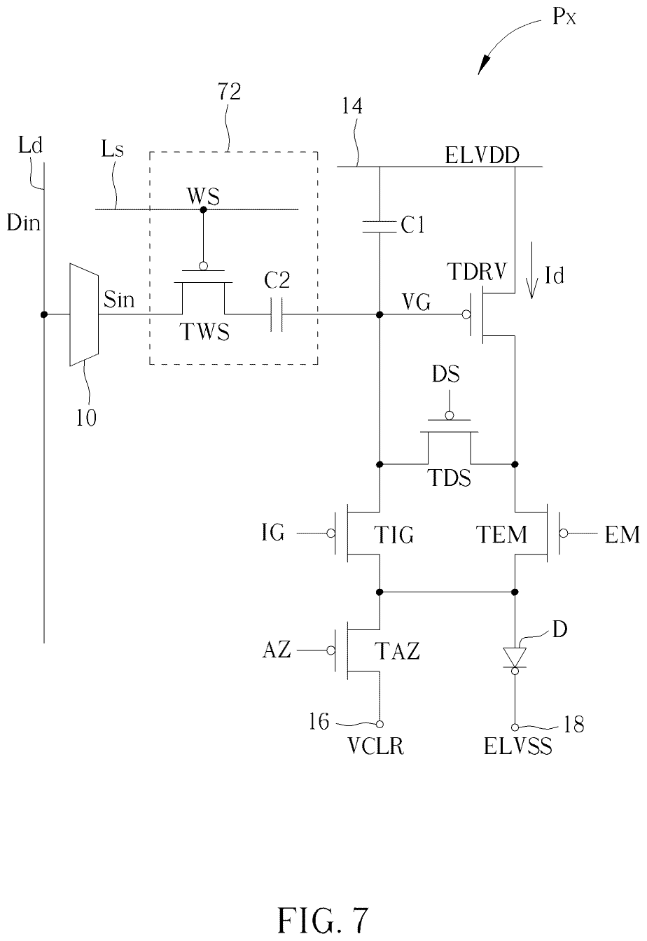

FIG. 7 is a schematic diagram of a pixel circuit Px according to another embodiment of the invention. The pixel circuit Px in FIG. 7 employs a sample circuit 72 to replace the sample circuit 12 in the pixel circuit Px in FIG. 1. The following discussion will focus on the sample circuit 72, the other components in FIG. 7 are configured and operated in a manner similar to those in FIG. 1, and the explanation therefor will be omitted here for brevity.

The sample circuit 72 includes the sample transistor TWS and the sense capacitor C2. The sample transistor TWS includes a control terminal coupled to the scan line Ls to receive the scan signal WS, a first terminal coupled to the data line Ld via the demultiplexer 10 to receive the input signal Sin, and a second terminal. The sense capacitor C2 includes a first terminal coupled to the second terminal of the sample transistor TWS, and a second terminal coupled to the control terminal of the driving transistor TDRV.

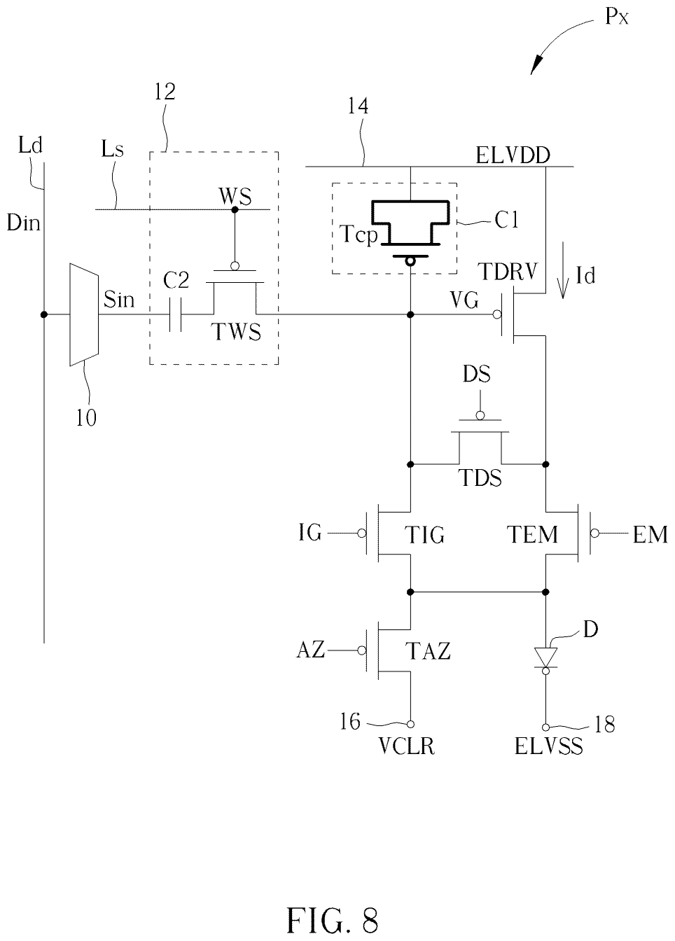

FIG. 8 is a schematic diagram of a pixel circuit Px according to another embodiment of the invention. The pixel circuit Px in FIG. 8 employs a hold transistor Tcp to implement the hold capacitor C1. The following discussion will focus on the hold transistor Tcp, the other components in FIG. 8 are configured and operated in a manner similar to those in FIG. 1, and the explanation therefor will be omitted here for brevity.

The hold capacitor C1 may include the hold transistor Tcp (seventh transistor). The hold transistor Top includes a control terminal coupled to the control terminal of the driving transistor TDRV, a first terminal coupled to the supply terminal 14, and a second terminal coupled to the supply terminal 14. The hold transistor Tcp is a P-type MOSFET in FIG. 8

Various embodiments of the pixel circuit Px in the invention are provided to (1) initiate the gate voltage VG of the driving transistor TDRV, ensuring accurate extraction of the threshold voltage Vth of the driving transistor TDRV; (2) transmit the offset voltage Vofs and the data voltage Vdat using a common data line, saving the circuit area; (3) employ a voltage divider (formed by the hold capacitor C1 and the sense capacitor C2) to enhance the step size of a gray level, increasing the operation range of the input signal Sin while delivering the required driving current Id; (4) employ the isolation transistor TIG/TIG5 to disconnect the leakage paths between the supply terminal 14 and reset terminal 16 and between the supply terminal 14 and the ground terminal 18 in the initial mode, the compensation mode and the program mode, reducing or eliminating the DC power loss; and (5) employ the sample transistor TWS and the sense capacitor C2 in the sample circuit to sense the data voltage during the program mode, and disconnected from the data line after the data voltage is stabilized, for the pixel circuit Px in the next row to gain access to the data line.

Those skilled in the art will readily observe that numerous modifications and alterations of the device and method may be made while retaining the teachings of the invention. Accordingly, the above disclosure should be construed as limited only by the metes and bounds of the appended claims.

1. A pixel circuit, the pixel circuit comprising:
a sample circuit;
a first transistor comprising a control terminal coupled to the sample circuit, a first terminal coupled to a supply terminal, and a second terminal;
a second transistor comprising a first terminal coupled to the control terminal of the first transistor, and a second terminal coupled to the second terminal of the first transistor;
a third transistor comprising a first terminal coupled to the second terminal of the first transistor, and a second terminal;
a light-emitting diode (LED) comprising a first terminal coupled to the second terminal of the third transistor, and a second terminal coupled to a ground terminal; and
a fourth transistor comprising a first terminal coupled to the first terminal of the light-emitting diode, and a second terminal coupled to a reset terminal;
wherein in an initial mode, the sample circuit is enabled and the fourth transistor is turned on.

2. (canceled)

3. The pixel circuit of claim 1, wherein the pixel circuit is switched to a compensation mode after the initial mode.

4. The pixel circuit of claim 3, wherein:
in the compensation mode, the sample circuit is enabled, the fourth transistor is turned on, the second transistor is turned on, and the third transistor is turned off;
in a program mode, the sample circuit is enabled, the fourth transistor is turned on, the second transistor is turned off, and the third transistor is turned off; and
in an emission mode, the sample circuit is disabled, the fourth transistor is turned off, the second transistor is turned off, and the third transistor is turned on.

5. The pixel circuit of claim 1, wherein the sample circuit comprises:
a sense capacitor comprising a first terminal, and a second terminal; and
a fifth transistor comprising a first terminal coupled to the second terminal of the sense capacitor; and a second terminal coupled to the control terminal of the first transistor.

6. The pixel circuit of claim 1, wherein the sample circuit comprises:
a fifth transistor comprising a first terminal; and a second terminal; and
a sense capacitor comprising a first terminal coupled to the second terminal of the fifth transistor, and a second terminal coupled to the control terminal of the first transistor.

7. The pixel circuit of claim 3, further comprising:
a sixth transistor comprising a first terminal coupled to the first terminal of the second transistor; and a second terminal coupled to the first terminal of the fourth transistor.

8. The pixel circuit of claim 7, wherein:
in the initial mode, the sixth transistor is turned on, the second transistor is turned off, and the third transistor is turned off; and
in the compensation mode, a program mode and an emission mode, the sixth transistor is turned off.

9. The pixel circuit of claim 1, further comprising:
a hold capacitor comprising a first terminal coupled to the supply terminal, and a second terminal coupled to the control terminal of the first transistor.

10. The pixel circuit of claim 8, wherein the hold capacitor comprises a seventh transistor comprising a control terminal coupled to control terminal of the first transistor, a first terminal coupled to the supply terminal, and a second terminal coupled to the supply terminal.

11. The pixel circuit of claim 3, further comprising:
a sixth transistor comprising a first terminal coupled to the supply terminal; and
a second terminal coupled to the first terminal of the first transistor.

12. The pixel circuit of claim 11, wherein:
in the initial mode, the sixth transistor is turned off, the second transistor is turned on, and the third transistor is turned on; and
in the compensation mode, a program mode and an emission mode, the sixth transistor is turned on.

13. A display device comprising:
a plurality of scan lines;
a plurality of data lines; and
a pixel array comprising a row of pixel circuits, each of the row of pixel circuits comprising:
a sample circuit coupled to one of the plurality of scan lines and one of the plurality of data lines;
a first transistor comprising a control terminal coupled to the sample circuit, a first terminal coupled to a supply terminal, and a second terminal;
a second transistor comprising a first terminal coupled to the control terminal of the first transistor, and a second terminal coupled to the second terminal of the first transistor;
a third transistor comprising a first terminal coupled to the second terminal of the first transistor, and a second terminal;
a light-emitting diode (LED) comprising a first terminal coupled to the second terminal of the third transistor, and a second terminal coupled to a ground terminal; and
a fourth transistor comprising a first terminal coupled to the first terminal of the light-emitting diode and a second terminal, and a second terminal coupled to a reset terminal;
wherein in an initial mode, the sample circuit is enabled and the fourth transistor is turned on.

14. (canceled)

15. The display device of claim 13, wherein the each of the row of pixel circuits is switched to a compensation mode after the initial mode.

16. The display device of claim 15, wherein:
in the compensation mode, the sample circuit is enabled, the fourth transistor is turned on, the second transistor is turned on, and the third transistor is turned off;
in a program mode, the sample circuit is enabled, the fourth transistor is turned on, the second transistor is turned off, and the third transistor is turned off; and
in an emission mode, the sample circuit is disabled, the fourth transistor is turned off, the second transistor is turned off, and the third transistor is turned on.

17. The display device of claim 13, wherein the sample circuit comprises:
a sense capacitor comprising a first terminal coupled to the one of the plurality of data lines, and a second terminal; and
a fifth transistor comprising a control terminal coupled to the one of the plurality of scan lines, a first terminal coupled to the second terminal of the sense capacitor; and a second terminal coupled to the control terminal of the first transistor.

18. The display device of claim 13, wherein the sample circuit comprises:
a fifth transistor comprising a control terminal coupled to the one of the plurality of scan lines, a first terminal coupled to the one of the plurality of data lines; and a second terminal; and
a sense capacitor comprising a first terminal coupled to the second terminal of the fifth transistor, and a second terminal coupled to the control terminal of the first transistor.

19. The display device of claim 15, wherein the each pixel circuit further comprises:
a sixth transistor comprising a first terminal coupled to the first terminal of the second transistor; and a second terminal coupled to the first terminal of the fourth transistor.

20. The display device of claim 19, wherein:
in the initial mode, the sixth transistor is turned on, the second transistor is turned off, and the third transistor is turned off; and
in the compensation mode, a program mode and an emission mode, the sixth transistor is turned off.

21. The display device of claim 15, wherein the each pixel circuit further comprises:
a sixth transistor comprising a first terminal coupled to the supply terminal; and
a second terminal coupled to the first terminal of the first transistor.

22. The display device of claim 21, wherein:
in the initial mode, the sixth transistor is turned off, the second transistor is turned on, and the third transistor is turned on; and
in the compensation mode, a program mode and an emission mode, the sixth transistor is turned on.

23. A pixel circuit, the pixel circuit comprising:
a sample circuit;
a first transistor comprising a control terminal coupled to the sample circuit, a first terminal coupled to a supply terminal, and a second terminal;
a second transistor comprising a first terminal coupled to the control terminal of the first transistor, and a second terminal coupled to the second terminal of the first transistor;
a third transistor comprising a first terminal coupled to the second terminal of the first transistor, and a second terminal;
a light-emitting diode (LED) comprising a first terminal coupled to the second terminal of the third transistor, and a second terminal coupled to a ground terminal; and
a fourth transistor comprising a first terminal coupled to the first terminal of the light-emitting diode and a second terminal, and a second terminal coupled to a reset terminal;
wherein the pixel circuit is switched to a compensation mode after an initial mode;
in the compensation mode, the sample circuit is enabled, the fourth transistor is turned on, the second transistor is turned on, and the third transistor is turned off;
in a program mode, the sample circuit is enabled, the fourth transistor is turned on, the second transistor is turned off, and the third transistor is turned off; and
in an emission mode, the sample circuit is disabled, the fourth transistor is turned off, the second transistor is turned off, and the third transistor is turned on.
